(19) United States
(12) Patent Application Publication
(10) Pub. No.: US 2025/0046616 A1
(43) Pub. Date: Feb. 6, 2025

(54) SUBSTRATE PROCESSING METHOD

(71) Applicant: SCREEN Holdings Co., Ltd., Kyoto (JP)

(72) Inventors: Linh Da HO, Kyoto (JP); Masaki INABA, Kyoto (JP)

(21) Appl. No.: 18/718,570

(22) PCT Filed: Nov. 30, 2022
(86) PCT No.: PCT/JP2022/044116

§ 371 Date: Jun. 11, 2024

(30) Foreign Application Priority Data
Dec. 17, 2021 (JP) 2021-205312

(51) Int. Cl. H01L 21/311; H01L 21/02

(52) U.S. Cl. CPC H01L 21/31111; H01L 21/0206

(57) ABSTRACT

A substrate processing method processes a substrate having a major surface in which at least one of a silicon oxide layer and a silicon nitride layer is exposed as a processing target layer. The substrate processing method includes an etching liquid supply step of supplying the major surface of the substrate with an etching liquid containing an ammonium fluoride as an etching agent to etch the processing target layer, a heating step of heating the etching liquid on the major surface of the substrate after the etching liquid supply step, and a rinse liquid supply step of supplying the major surface of the substrate with a rinse liquid after the heating step.

### RELATED APPLICATIONS

This application claims the benefit of priority to Japanese Patent Application No. 2021-205312 filed on Dec. 17, 2021. The entire contents of this application are hereby incorporated herein by reference.

### TECHNICAL FIELD

The present invention relates to a substrate processing method that processes a substrate. The substrates to be processed include a semiconductor wafer, a substrate for a FPD (flat panel display) such as a liquid crystal display and an organic EL (electroluminescence) display, a substrate for an optical disc, a substrate for a magnetic disc, a substrate for a magneto-optical disc, a substrate for a photomask, a ceramic substrate, a substrate for a solar cell, and the like, for example.

### BACKGROUND ART

The following Patent Literature 1 discloses substrate processing in which a substrate that includes a dielectric layer is etched by a process gas that includes: a fluorocarbon gas including a first group of fluorocarbon (CHF₃, for example) that contains hydrogen and a second group of fluorocarbon (C₄F₈, for example) that does not contain hydrogen; a carbon-oxygen containing gas such as CO; and a nitrogen containing gas such as N₂.

### CITATION LIST

### Patent Literature

Patent Literature 1: JP H1041274 A

### SUMMARY OF INVENTION

### Technical Problem

Patent Literature 1 discloses that etching with high selectivity can be achieved by the above-mentioned substrate processing. However, in the substrate processing disclosed in Patent Literature 1, it is difficult to stop a reaction between a process gas and the substrate at a desired etching depth. An embodiment of the present invention provides a substrate processing method that can accurately control an etching depth.

### Solution to Problem

An embodiment of the present invention provides a substrate processing method that processes a substrate having a major surface in which at least one of a silicon oxide layer and a silicon nitride layer is exposed as a processing target layer. The substrate processing method includes an etching liquid supply step of supplying the major surface of the substrate with an etching liquid containing an ammonium fluoride as an etching agent to etch the processing target layer, a heating step of heating the etching liquid on the major surface of the substrate after the etching liquid supply step, and a rinse liquid supply step of supplying the major surface of the substrate with a rinse liquid after the heating step.

According to this method, the processing target layer is at least one of the silicon oxide layer and silicon nitride layer, and the etching liquid contains ammonium fluoride as an etching agent. Accordingly, it is possible to make the processing target layer and the etching agent existing on the major surface of the substrate speedily react with each other by heating and hence, time dependency of etching of the processing target layer can be reduced. That is, saturated atomic layer etching can be achieved.

The saturated atomic layer etching is etching that can control a depth of etching by stopping the etching in a predetermined process time. By repeating the saturated atomic layer etching multiple cycles, a desired etching depth can be easily achieved. To be more specific, one cycle of etching is stopped within several tens seconds and hence, an etching depth of several nm to several tens nm can be achieved.

According to an embodiment of the present invention, the substrate processing method further includes a rotating step of rotating the substrate about a center axis that passes a center portion of the major surface of the substrate after stopping the supply of the etching liquid to the major surface of the substrate in the etching liquid supply step and before the heating step.

According to this method, the substrate is rotated after the supply of the etching liquid to the major surface of the substrate is stopped. Accordingly, an amount of the etching liquid on the major surface of the substrate can be moderately reduced, and a total amount of the etching agent existing on the major surface of the substrate can be controlled. If the total amount of the etching agent can be controlled, an etching amount of the processing target layer can be easily controlled. Particularly, by rotating the substrate at a rotational speed of not less than 2000 rpm and not more than 4000 rpm, a total amount of the etching agent existing on the major surface of the substrate can be accurately controlled.

In an embodiment of the present invention, a mass percent concentration of the etching agent in the etching liquid to be supplied to a major surface of the substrate is not less than 0.2 wt % and less than 10 wt %. In a case where the mass percent concentration of the etching agent in the etching liquid is set to not less than 0.2 wt % and less than 10 wt %, the saturated atomic layer etching can be easily achieved.

In an embodiment of the present invention, in the heating step, the substrate is heated to a temperature of not less than 50° C. and not more than 200° C. In a case where the heating temperature of the etching liquid is not less than 50° C. and not more than 200° C., it is possible to make the processing target layer and the etching agent existing on the major surface of the substrate react with each other particularly speedily.

In an embodiment of the present invention, an etching depth of the processing target layer is proportional to a total amount of the etching agent in the etching liquid existing on a major surface of the substrate at the time of starting the heating step. Accordingly, the etching depth can be accurately controlled by controlling an amount of the etching agent existing on the major surface of the substrate at the time of starting the heating step.

According to an embodiment of the present invention, the heating step includes a reaction promoting step of promoting a reaction between the etching agent and the processing target layer by removing by heating a solid layer that is formed on the processing target layer by a reaction between the etching agent in the etching liquid on the major surface of the substrate and the processing target layer.

According to this method, the solid layer that is formed by a reaction between the etching agent and the processing target layer can be removed by heating and hence, the reaction between the etching agent and the processing target layer is promoted. Accordingly, it is possible to make the processing target layer and the etching agent existing on the major surface of the substrate react with each other more speedily.

In an embodiment of the present invention, the substrate may further include an insulation layer, a channel that is formed by digging a front surface of the insulation layer and in that the processing target layer is embedded, and a covering layer interposed between the processing target layer and a side wall of the channel and covering the side wall of the channel. Also, the substrate may further include a semiconductor layer, and a plurality of structural bodies formed on the semiconductor layer, the plurality of structural bodies having the processing target layer positioned therebetween.

The above and other objects, features, and advantages of the present invention will become more apparent from the following detailed description of the embodiments with reference to the attached drawings.

### BRIEF DESCRIPTION OF THE DRAWINGS

FIG. 1 is an illustrative plan view illustrating a layout of a substrate processing apparatus according to a first embodiment of the present invention.

FIG. 2 is a schematic view for describing the configuration of a wet processing unit provided in the substrate processing apparatus.

FIG. 3 is a block diagram for describing the electrical configuration of the substrate processing apparatus.

FIG. 4 is a flowchart for describing substrate processing that is performed by the substrate processing apparatus.

FIG. 5 is a schematic view for describing a state of an upper surface of a substrate during the substrate processing.

FIG. 6 is a schematic view for describing one example of a mechanism at the time of etching a processing target layer that is exposed from the upper surface of the substrate.

FIG. 7A is a schematic view for describing one example of the structure of a surface layer portion on an upper surface of the substrate to be processed by the substrate processing apparatus.

FIG. 7B is a schematic view for describing a change in the structure due to etching of the surface layer portion on the upper surface of the substrate illustrated in FIG. 7A.

FIG. 8A is a schematic view for describing another example of the structure of the surface layer portion on the upper surface of the substrate to be processed by the substrate processing apparatus.

FIG. 8B is a schematic view for describing a change in the structure due to etching of the surface layer portion on the upper surface of the substrate illustrated in FIG. 8A.

FIG. 9 is a schematic view for illustrating a modification of the wet processing unit.

FIG. 10 is an illustrative plan view illustrating a layout of a substrate processing apparatus according to a second embodiment of the present invention.

FIG. 11 is a schematic view for describing the configuration of a wet processing unit provided in the substrate processing apparatus according to the second embodiment.

FIG. 12 is a schematic view for describing the configuration of a dry processing unit provided in the substrate processing apparatus according to the second embodiment.

FIG. 13A is a schematic view for describing steps of a change-with-time test for observing time dependency of etching.

FIG. 13B is a graph illustrating results of the change-with-time test.

FIG. 14 is a graph illustrating results of a concentration change test for observing concentration dependency of etching.

FIG. 15 is a table illustrating results of a crystal observation test for observing the generation of crystals in an etching liquid.

FIG. 16 is a graph illustrating results of a change-in-rotational-speed test for observing substrate rotational speed dependency of etching.

FIG. 17 is a graph illustrating results of a change-in-temperature test for observing heating temperature dependency of etching.

### DESCRIPTION OF EMBODIMENTS

### <Configuration of Substrate Processing Apparatus According to First Embodiment>

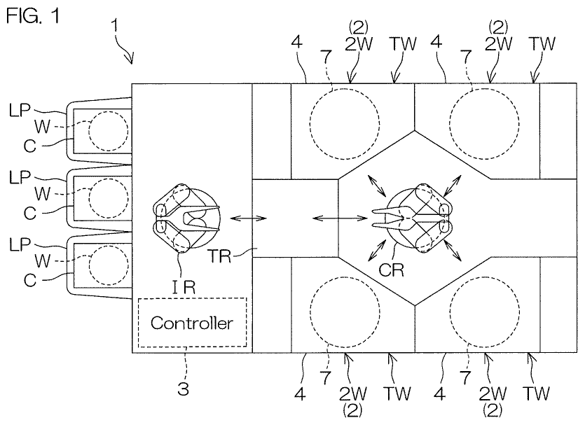

FIG. 1 is an illustrative plan view illustrating a layout of a substrate processing apparatus 1 according to a first embodiment of the present invention.

The substrate processing apparatus 1 is a single substrate processing type apparatus that processes a substrate W one by one. In this embodiment, the substrate W has a circular shape. The substrate W has a pair of major surfaces. At least one of a silicon oxide layer (SiO₂ layer) and a silicon nitride layer (SiN layer) as a processing target layer is exposed from at least one major surface of the pair of major surfaces of the substrate W. The substrate processing apparatus 1 includes: a plurality of processing units 2 that process the substrate W; load ports LP on each of which a carrier C that accommodates a plurality of substrates W to be processed by the processing units 2 is mounted; and transfer robots IR, CR that transfer the substrates W between the load ports LP and the processing units 2; and a controller 3 that controls the substrate processing apparatus 1.

The transfer robot IR transfers the substrate W between the carrier C and the transfer robot CR. The transfer robot CR transfers the substrate W between the transfer robot IR and the processing unit 2. The transfer robots IR and CR are arranged on a transfer path TR that extends toward the plurality of processing units 2 from the plurality of the load ports LP.

The plurality of processing units 2 have the same configuration, for example. The plurality of processing units 2 form four processing towers TW that are respectively arranged at four positions spaced apart from each other horizontally. Each processing tower TW includes a plurality of (three, for example) processing units 2 that are stacked in the vertical direction. Four processing towers TW are arranged on both sides of the transfer path TR such that two processing towers TW are disposed on each side.

The processing unit 2 is formed of a wet processing unit 2W that processes the substrate W with a processing liquid. Although the processing unit 2 is described below in detail, as a processing liquid that is supplied to the substrate W in the wet processing unit 2W, an etching agent, a rinse liquid and the like are mentioned.

Each wet processing unit 2W includes a processing cup 7 and a chamber 4 that houses the processing cup 7. The chamber 4 includes an inlet/outlet (not illustrated in the drawing) for carrying in/out the substrate W by the transfer robot CR. The chamber 4 includes a shutter unit (not illustrated in the drawing) that opens/closes the inlet/outlet.

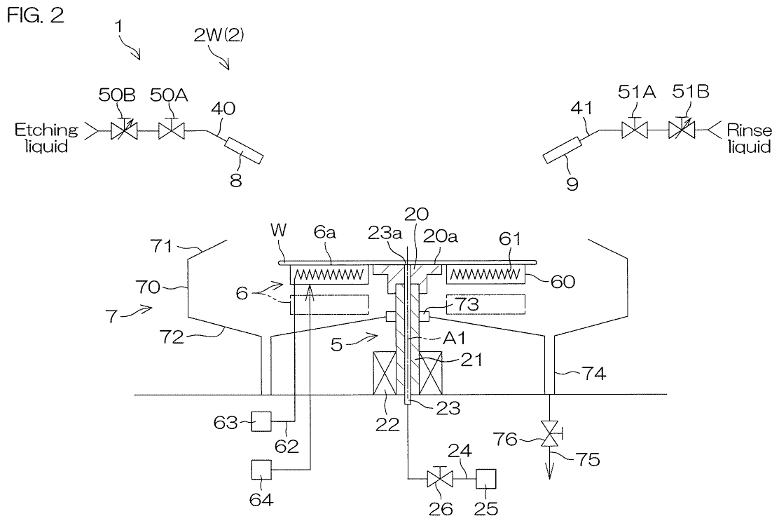

FIG. 2 is a schematic view for describing the configuration of the wet processing unit 2W.

The wet processing unit 2W further includes a spin chuck 5 that rotates the substrate W about a rotational axis A1 while holding the substrate W at a predetermined holding position, a heating unit 6 that has a heating surface 6a that faces a lower surface of the substrate W and heats the substrate W, and a plurality of processing liquid nozzles (an etching liquid nozzle 8 and a rinse liquid nozzle 9) that eject a processing liquid toward an upper surface (the major surface on an upper side) of the substrate W held by the spin chuck 5. The holding position is a position that is aligned with a center axis along which the rotational axis A1 passes a center portion of the upper surface of the substrate W, and is a position at which the upper surface of the substrate W is horizontal.

The spin chuck 5 and the plurality of processing liquid nozzles are disposed in the chamber 4 (see FIG. 1) together with the processing cup 7.

The spin chuck 5 is surrounded by the processing cup 7. The spin chuck 5 includes: a spin base 20 that suctions a lower surface of the substrate W and holds the substrate W at a predetermined position; a rotary shaft 21 that extends along the rotational axis A1 and is connected to the spin base 20; and a rotation driving mechanism 22 that rotates the rotary shaft 21 about the rotational axis A1.

The spin base 20 includes a suction surface 20a that is suctioned to the lower surface of the substrate W. The suction surface 20a is, for example, the upper surface of the spin base 20. The suction surface 20a is, for example, a circular surface having a center portion through which the rotational axis A1 passes. A diameter of the suction surface 20a is smaller than a diameter of the substrate W.

A suction path 23 is inserted into the spin base 20 and the rotary shaft 21. The suction path 23 has a suction opening 23a that is exposed from the center of the suction surface 20a of the spin base 20. The suction path 23 is connected to a suction pipe 24. The suction pipe 24 is connected to a suction device 25 such as a vacuum pump. The suction device 25 may constitute a portion of the substrate processing apparatus 1, and may be a device separate from the substrate processing apparatus 1 provided in a facility where the substrate processing apparatus 1 is installed.

A suction valve 26 that opens/closes the suction pipe 24 is provided on the suction pipe 24. By opening the suction valve 26, the substrate W that is disposed on the suction surface 20a of the spin base 20 is suctioned to the suction opening 23a of the suction path 23. Accordingly, the substrate W is suctioned to the suction surface 20a from below, and is held at the holding position. The posture of the substrate W held at the holding position is, for example, a posture where the upper surface of the substrate W follows the horizontal direction. Further, centering of the substrate W may be performed such that the center axis of the substrate W is aligned with the rotational axis A1 by a centering unit not illustrated in the drawing.

The rotation driving mechanism 22 includes, for example, an actuator such as an electric motor. When the rotary shaft 21 is rotated by the rotation driving mechanism 22, the spin base 20 is rotated. As a result, the substrate W is rotated about the rotational axis A1 together with the spin base 20.

The spin base 20 is one example of a substrate holding member that holds the substrate W at the predetermined holding position. The spin chuck 5 is one example of a rotary holding unit that rotates the substrate W about the rotational axis A1 while holding the substrate W at the predetermined holding position. The spin chuck 5 is also referred to as a suction rotary unit that rotates the substrate W while sucking the substrate W to the suction surface 20a.

The plurality of processing liquid nozzles include: an etching liquid nozzle 8 that ejects a continuous flow of an etching liquid toward the upper surface of the substrate W held by the spin chuck 5; and a rinse liquid nozzle 9 that ejects a continuous flow of a rinse liquid toward the upper surface of the substrate W held by the spin chuck 5.

An etching liquid ejected from the etching liquid nozzle 8 contains: an etching agent that is used as a solute; and a solvent that dissolves the etching agent. The etching agent is a material that has a property of etching a processing target layer that is exposed from the major surface of the substrate W. The etching agent contains ammonium fluoride (NH₄F).

It is sufficient for the solvent that the solvent can dissolve an etching agent. For example, pure water such as deionized water (DIW) can be used as the solvent. Accordingly, as the etching liquid, an aqueous ammonium fluoride solution can be used. The solvent is not limited to DIW, and a solvent can be also selected from liquids that are used as a rinse liquid described below.

The etching agent forms a solid layer that contains a thermally decomposable solid matter by reacting with a processing target layer. Ammonium fluoride that is used as the etching agent reacts with silicon oxide that forms the processing target layer in accordance with the following chemical reaction formula 1 and the following chemical reaction formula 2.

To be more specific, as expressed in the chemical reaction formula 1, ammonium fluoride and silicon dioxide react with each other thus forming mainly a solid layer that contains ammonium fluorosilicate ((NH₄)₂SiF₆) in a solid state. As expressed in the chemical reaction formula 2, ammonium fluorosilicate is decomposed by heating. Due to the decomposition of ammonium fluorosilicate, ammonium (NH₃), hydrogen fluoride (HF) and silicon tetrafluoride (SiF₄) are produced. All these materials are gases at their respective reaction temperatures.

6NH₄F+SiO₂→(NH₄)₂SiF₆(s)+2H₂O+4NH₃ [Chemical formula 1]

(NH₄)₂SiF₆(s) [symbol] 2NH₃(g)+2HF(g)+SiF₄(g) [Chemical formula 2]

Even in a case where a processing target layer

contains silicon nitride, a solid layer that contains ammonium fluorosilicate in a solid state is formed.

It is preferable that the mass percent concentration of an etching agent in an etching liquid be not less than 0.2 wt % and less than 10 wt %. It is more preferable that the mass percent concentration of an etching agent in an etching liquid be not less than 0.2 wt % and not more than 7.0 wt %. It is further preferable that the mass percent concentration of an etching agent in an etching liquid be not less than 2.0 wt % and not more than 7.0 wt %. It is still further preferable that the mass percent concentration of an etching agent in an etching liquid be not less than 2.0 wt % and not more than 6.0 wt %.

A rinse liquid ejected from the rinse liquid nozzle 9 is pure water such as deionized water (DIW), for example. However, a rinse liquid is not limited to DIW. A rinse liquid may be carbonated water, electrolytic ionized water, aqueous hydrochloric acid solution having dilution concentration (for example, not less than 1 ppm and not more than 100 ppm), ammonium water having dilution concentration (for example, not less than 1 ppm and not more than 100 ppm) or reduction water (hydrogen water).

In this embodiment, each processing liquid nozzle is a fixed nozzle where the nozzle positions in the vertical direction and the horizontal direction are fixed.

To the etching liquid nozzle 8, an etching liquid pipe 40 that guides an etching liquid to the etching liquid nozzle 8 is connected. To the etching liquid pipe 40, an etching liquid valve 50A that opens/closes a flow path in the etching liquid pipe 40, and an etching liquid flow rate adjustment valve 50B that adjusts a flow rate of an etching liquid in the etching liquid pipe 40 are provided. Providing the valve in the pipe may also mean that the valve is interposed in the pipe. By opening the etching liquid valve 50A, an etching liquid is ejected from the etching liquid nozzle 8 at a flow rate corresponding to the degree of opening of the etching liquid flow rate adjustment valve 50B.

To the rinse liquid nozzle 9, a rinse liquid pipe 41 that guides a rinse liquid to the rinse liquid nozzle 9 is connected. In the rinse liquid pipe 41, a rinse liquid valve 51A that opens/closes a flow path in the rinse liquid pipe 41, and a rinse liquid flow rate adjustment valve 51B that adjusts a flow rate of a rinse liquid in the rinse liquid pipe 41 are provided. By opening the rinse liquid valve 51A, a rinse liquid is discharged from the rinse liquid nozzle 9 at a flow rate corresponding to the degree of opening of the rinse liquid flow rate adjustment valve 51B.

The heating unit 6 is, for example, a hot plate that heats the substrate W. The heating unit 6 includes: a plate body 60 that faces the substrate W from below; and a heater 61 incorporated in the plate body 60. The heating unit 6 is formed in an annular shape that surrounds the spin base 20. A heating surface 6a is formed of the upper surface of the plate body 60, for example. The heating surface 6a may be an annular surface that surrounds the spin base 20. The heater 61 may be a resistor that is incorporated in the plate body 60. Electricity is supplied to the heater 61 from an energizing unit 63 such as a power source via an electricity supply line 62. A setting temperature of the heater 61 of the heating unit 6 is, for example, not less than 50° C. and not more than 200° C.

The heating unit 6 is elevated/lowered in a vertical direction by a heater elevating/lowering mechanism 64. The heater elevating/lowering mechanism 64 elevates/lowers the heating unit 6 between a contact heating position (the position indicated by a solid line in FIG. 2) at which the heating unit 6 heats the substrate W in a state where the heating unit 6 is in contact with the substrate W, and a non-heating position (the position indicated by an alternate long and two short dashes line in FIG. 2) at which the heating unit 6 is spaced apart from the substrate W so that the substrate W is not heated. The heating unit 6 can heat, when the heating unit 6 is positioned at the contact heating position, the substrate W and a liquid on the substrate W to a temperature of not less than 50° C. and not more than 200° C.

The heating unit 6 can be arranged at a non-contact heating position at which the heating unit 6 heats the substrate W in a state where the heating unit 6 is not in contact with the lower surface of the substrate W. The non-contact heating position is a position closer to the lower surface of the substrate W than the non-heating position.

The heater elevating/lowering mechanism 64 includes, for example, a ball screw mechanism (not illustrated in the drawing) that is joined to the plate body 60, and a motor (not illustrated in the drawing) that applies a driving force to the ball screw mechanism. The heater elevating/lowering mechanism 64 is also referred to as a heater lifter.

The processing cup 7 is a member that receives a processing liquid discharged from the substrate W. The processing cup 7 includes: a circular cylindrical portion 70 that extends in a vertical direction; an inclined portion 71 that extends obliquely and upwardly from an upper end of the circular cylindrical portion 70; and a substantially annular bottom portion 72 to which a processing liquid received by the inclined portion 71 and the circular cylindrical portion 70 is guided. A sealing member 73 such as a labyrinth seal is disposed between an inner peripheral end of the bottom portion 72 and the rotary shaft 21. With the provision of the sealing member 73, leakage of a processing liquid from the bottom portion 72 of the processing cup 7 is prevented.

A liquid discharge groove 74 is disposed on the bottom portion 72, and the liquid discharge groove 74 is connected to a liquid discharge pipe 75. A liquid discharge valve 76 is provided on the liquid discharge pipe 75. By opening the liquid discharge valve 76, a processing liquid is discharged from the liquid discharge pipe 75 as a discharge liquid.

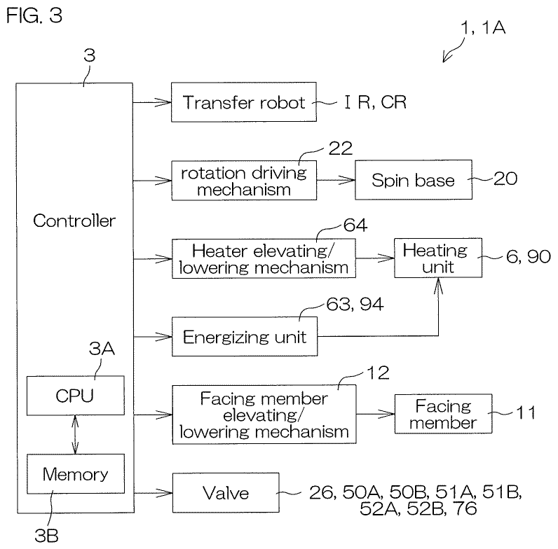

FIG. 3 is a block diagram for describing the electrical configuration of the substrate processing apparatus 1. The controller 3 includes a microcomputer, and controls a controlled object provided in the substrate processing apparatus 1 in accordance with a predetermined control program.

To be more specific, the controller 3 includes a processor 3A (CPU) and a memory 3B in which a control program is stored. The controller 3 is arranged to perform various controls for substrate processing by allowing the processor 3A to execute a control program. Particularly, the controller 3 is programed such as to control the transfer robots IR, CR, the rotation driving mechanism 22, the heater elevating/lowering mechanism 64, the energizing unit 63, the suction valve 26, the etching liquid valve 50A, the etching liquid flow rate adjustment valve 50B, the rinse liquid valve 51A, the rinse liquid flow rate adjustment valve 51B, the liquid discharge valve 76, and the like.

Further, in FIG. 3, representative members are illustrated. However, with respect to members that are not illustrated, it is not intended that such members are not controlled by the controller 3, and the controller 3 can properly control the respective members provided in the substrate processing apparatus 1. In FIG. 3, members that are described in modifications and a second embodiment descried later are also illustrated, and these members are also controlled by the controller 3.

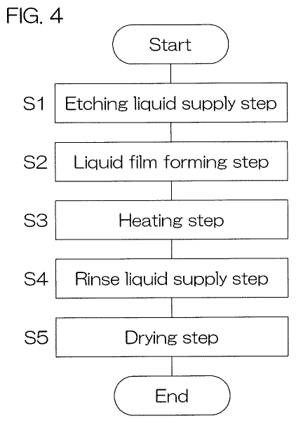

The respective steps illustrated in FIG. 4 that are described below are performed by controlling the respective members provided in the substrate processing apparatus 1 using the controller 3. In other words, the controller 3 is programed such as to perform the respective steps illustrated in FIG. 4 described below.

### <One Example of Substrate Processing>

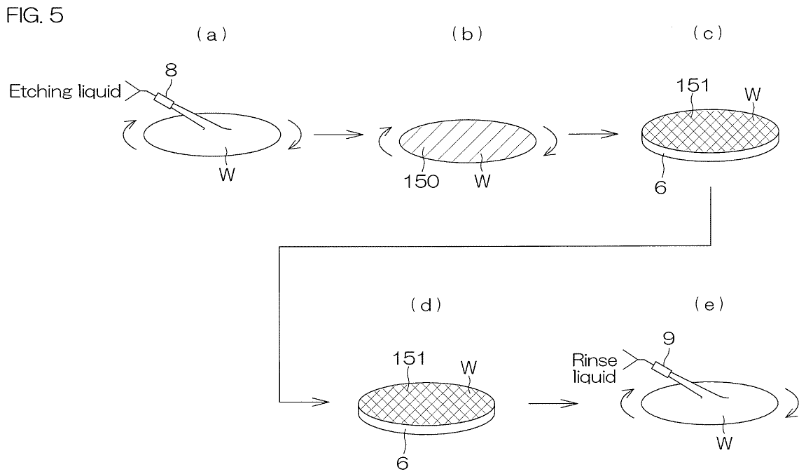

FIG. 4 is a flowchart for describing substrate processing performed by the substrate processing apparatus 1. FIG. 5 is a schematic view for describing a mode of the upper surface of the substrate W during the substrate processing.

In the substrate processing by the substrate processing apparatus 1, for example, as illustrated in FIG. 4, an etching liquid supply step (step S1), a liquid film forming step (step S2), a heating step (step S3), a rinse liquid supply step (step S4), and a drying step (step S5) are performed. Hereinafter, details of the substrate processing are described with reference mainly to FIG. 2 and FIG. 4. FIG. 5 is referenced when necessary.

First, an unprocessed substrate W is carried into the processing unit 2 from the carrier C by the transfer robots IR, CR (see FIG. 1), and is transferred to the spin chuck 5 (carry-in step). Accordingly, the substrate W is held at the holding position by the spin chuck 5 (substrate holding step). The substrate W is held by the spin chuck 5 such that the major surface from which a processing target layer is exposed forms the upper surface. The spin chuck 5 starts the rotation of the substrate W while holding the substrate W (rotating step). During the substrate processing being performed, the energizing unit 63 maintains an energizing state so that the heater 61 of the heating unit 6 is heated to a setting temperature (for example, not less than 50° C. and not more than 200° C.).

After the substrate W is held by the spin chuck 5, the etching liquid supply step (step S1) of supplying an etching liquid to the upper surface of the substrate W is performed. To be more specific, the etching liquid valve 50A is opened. As a result, as illustrated in FIG. 5(a), an etching liquid is ejected from the etching liquid nozzle 8, and the etching liquid reaches the upper surface of the substrate W. The etching liquid that reached the upper surface of the substrate W spreads over the entirety of the upper surface of the substrate W due to the action of a centrifugal force.

An ejection flow rate of an etching liquid from the etching liquid nozzle 8 is 2000 mL/min, for example. During a period in which the etching liquid is supplied to an upper surface of the substrate W, the substrate W is rotated at a rotational speed of not less than 300 rpm and not more than 700 rpm, for example.

Next, the liquid film forming step (step S2) of forming a thin liquid film 150 of an etching liquid on the upper surface of the substrate W is performed. To be more specific, in the etching liquid supply step, after an etching liquid is ejected from the etching liquid nozzle 8 for a predetermined period (for example, a period of not less than 5 seconds and not more than 15 seconds), the etching liquid valve 50A is closed. As a result, the ejection of the etching liquid from the etching liquid nozzle 8 is stopped so that the supply of an etching liquid to the upper surface of the substrate W is stopped. Even after the supply of the etching liquid to the upper surface of the substrate W is stopped, the rotation of the substrate W is continued (the rotation continuation step, the rotating step). As a result, the etching liquid is removed from the upper surface of the substrate W and, as illustrated in FIG. 5(b), the thin liquid film 150 (thin film) of the etching liquid is formed on the upper surface of the substrate W (the liquid film forming step, the film thinning step). A rotational speed of the substrate W after the ejection of the etching liquid is stopped, that is, the rotational speed of the substrate W in the liquid film forming step is not less than 2000 rpm and not more than 4000 rpm.

After the supply of the etching liquid is stopped, at a point in time that a predetermined liquid film forming time (for example, not less than 30 seconds and not more than 140 seconds) elapses, the heating step (step S3) of heating the substrate W is started. To be more specific, the rotation of the substrate W is stopped and, thereafter, the heater elevating/lowering mechanism 64 arranges the heating unit 6 at the contact heating position. With such an operation, as illustrated in FIG. 5(c), the liquid film 150 on the upper surface of the substrate W is heated through the substrate W. A heating temperature of the liquid film 150 is, for example, a setting temperature of the heating unit 6, that is, a temperature of not less than 50° C. and not more than 200° C. Due to heating of the liquid film 150, an etching action by an etching agent in the etching liquid is promoted. As illustrated in FIG. 5(d), a solid layer 151 is formed on the upper surface of the substrate W by a reaction between the etching agent and the processing target layer.

After the substrate W is heated for a predetermined heating time (for example, not less than 60 seconds and not more than 180 seconds), the rinse liquid supply step (step S4) of supplying a rinse liquid to the upper surface of the substrate W is performed. To be more specific, the heater elevating/lowering mechanism 64 arranges the heating unit 6 at the non-heating position. As a result, the heating applied to the substrate W is stopped. Then, the rotation of the substrate W is resumed and, also, the rinse liquid valve 51A is opened. Due to such operations, as illustrated in FIG. 5(e), a rinse liquid is ejected from the rinse liquid nozzle 9, and the rinse liquid reaches the upper surface of the substrate W in a rotating state. The rinse liquid that reached the upper surface of the substrate W spreads over the entirety of the upper surface of the substrate W due to the action of a centrifugal force. Accordingly, the solid layer 151 on the upper surface of the substrate W is dissolved by the rinse liquid while being discharged to the outside of the substrate W.

An ejection flow rate of a rinse liquid from the rinse liquid nozzle 9 is 2000 mL/min, for example. During a period in which the rinse liquid is supplied to the upper surface of the substrate W, the substrate W is rotated at a rotational speed of not less than 1000 rpm and not more than 2000 rpm or less.

Next, the drying step (step S5) of drying the upper surface of the substrate W by rotating the substrate W at a high speed is performed. To be more specific, the supply of the rinse liquid to the upper surface of the substrate W is stopped by closing the rinse liquid valve 51A.

Then, the rotation driving mechanism 22 accelerates the rotation of the substrate W so that the substrate W is rotated at a high speed (for example, 1500 rpm). As a result, a large centrifugal force acts on the rinse liquid adhering to the substrate W so that the rinse liquid is spun off to a periphery of the substrate W.

After the drying step (step S5), the rotation driving mechanism 22 stops the rotation of the substrate W. Then, the transfer robot CR enters the processing unit 2, receives the processed substrate W from the spin chuck 5, and carries out the processed substrate W to the outside of the processing unit 2 (carry-out step). The substrate W is transferred from the transfer robot CR to the transfer robot IR, and the substrate W is stored in the carrier C by the transfer robot IR.

According to the first embodiment, the processing target layer includes at least one of a silicon oxide layer and a silicon nitride layer, and the etching liquid contains ammonium fluoride as an etching agent. Accordingly, it is possible to make the processing target layer and the etching agent existing on the major surface of the substrate W speedily react with each other by heating and hence, time dependency of etching of the processing target layer can be reduced. That is, saturated atomic layer etching can be achieved.

After the etching liquid supply step and before the heating step, the substrate W is rotated. Accordingly, an amount of the etching liquid on the upper surface of the substrate W can be moderately reduced and a total amount of the etching agent existing on the major surface of the substrate W can be controlled. If the total amount of the etching agent can be controlled, an amount of etching of the processing target layer can be easily controlled. Particularly, by rotating the substrate W at a rotational speed of not less than 2000 rpm and not more than 4000 rpm, a total amount of the etching agent existing on the upper surface of the substrate W can be accurately controlled.

In a case where a mass percent concentration of the etching agent in the etching liquid is not less than 0.2 wt % and less than 10 wt %, the saturated atomic layer etching can be easily achieved.

If a heating temperature in the heating step is not less than 50° C. and not more than 200° C., it is possible to make the processing target layer and the etching agent existing on the major surface of the substrate react with each other particularly speedily.

### <One Example of Mechanism of Saturated Atomic Layer Etching>

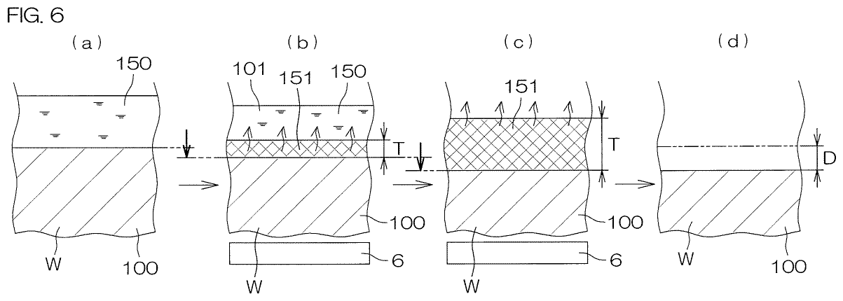

Next, the mechanism of saturated atomic layer etching is described. FIG. 6 is a schematic view for describing one example of the mechanism at the time of etching a processing target layer 100 exposed from the upper surface of the substrate W. In the liquid film forming step (step S2), as illustrated in FIG. 6(a), a liquid film 150 is formed on the upper surface of the substrate W.

A solid layer 151 is formed by a reaction between an etching agent in an etching liquid on the upper surface of the substrate W and the processing target layer 100. By heating the liquid film 150 through the substrate W in the heating step (step S3), as illustrated in FIG. 6(b), the formation of the solid layer 151 is promoted.

To describe in more detail, etching progresses as the etching liquid permeates into the solid layer 151 and reaches the processing target layer 100. Due to a progress of the etching, a thickness T of the solid layer 151 increases. On the other hand, decomposition of the solid layer 151 progresses by heating and hence, the reaction between the etching agent and the processing target layer 100 is promoted (the reaction promoting step).

To describe in further detail, a product produced by the decomposition of the solid layer 151 is a gas and hence, the gas is diffused in an atmosphere. As a result, the product produced as a result of the reaction between the etching liquid and the processing target layer 100 is removed from a reaction system. Since the product is removed, the decomposition of the solid layer 151 is promoted such as to increase an amount of the product produced by a thermal decomposition reaction.

As a final step, as illustrated in FIG. 6(c), the etching is finished at a point in time that the etching of the processing target layer 100 has progressed to an extent that most of the etching agent on the upper surface of the substrate W is consumed. In this manner, at least a portion of the solid layer 151 that is formed by a reaction between the etching agent and the processing target layer 100 is removed by heating and hence, the reaction between the etching agent and the processing target layer 100 is promoted.

The promotion of a reaction between the etching agent and the processing target layer 100 is specifically described using the chemical reaction formula 1 and the chemical reaction formula 2 described above. Ammonium fluorosilicate ((NH₄)₂SiF₆) is changed to various decomposed products (ammonium, hydrogen fluoride, silicon tetrafluoride) by decomposition. The various decomposed products are in a gaseous state at a reaction temperature and hence, the decomposed products are diffused in an atmosphere. As a result, the products produced by the reaction between the etching liquid and the processing target layer 100 (a reaction expressed in the chemical reaction formula 1) are removed from the reaction system. Accordingly, the decomposition of ammonium fluorosilicate is promoted such as to increase amounts of the products by a thermal decomposition reaction, and a reaction in the chemical reaction formula 2 progresses to a right side. Due to the progress of the reaction in the chemical reaction formula 2 to the right side, products produced by the reaction expressed by the chemical reaction formula 1 are reduced and hence, the chemical reaction formula 1 also causes a progress to a right side. That is, the reaction of ammonium fluoride (NH₄F) and silicon oxide (SiO₂) is promoted. Accordingly, the most of ammonium fluoride is consumed.

As a result, an etching depth D of the processing target layer 100 (see FIG. 6(d)) is proportional to a total amount of the etching agent in the etching liquid existing on the upper surface of the substrate W at the time of starting the heating step. Accordingly, by controlling an amount of the etching liquid existing on the upper surface of the substrate W at the time of starting the heating step, the etching depth D can be accurately controlled.

### <One Example of Change in Surface Layer Portion on Upper Surface of Substrate by Substrate Processing>

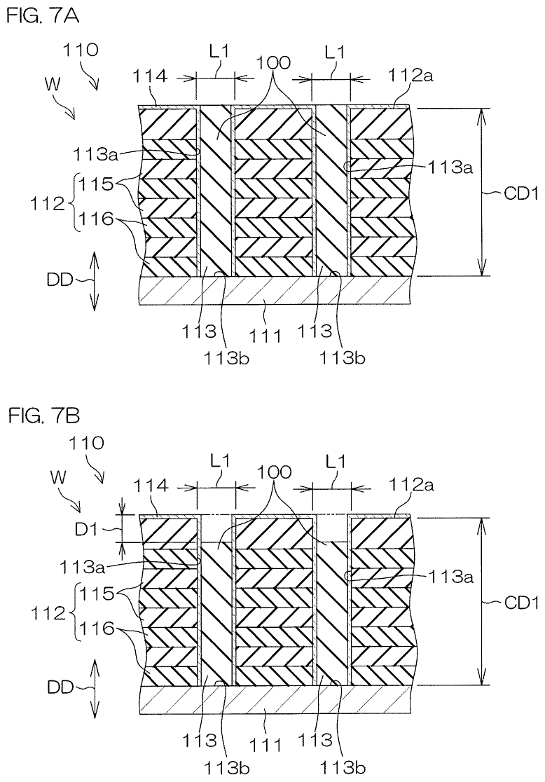

FIG. 7A is a schematic view for describing one example of the structure of a surface layer portion 110 on the upper surface of the substrate W to be processed by the substrate processing apparatus 1. FIG. 7B is a schematic view for describing a change in the structure due to etching of the surface layer portion 110 on the upper surface of the substrate W illustrated in FIG. 7A.

As illustrated in FIG. 7A, the surface layer portion 110 on the upper surface of the substrate W includes: a semiconductor layer 111, a laminated body 112 formed on a semiconductor layer 111; a plurality of channels 113 formed by digging the front surface of the laminated body 112; a plurality of processing target layers 100 respectively embedded in the plurality of channels 113; a covering layer 114 interposed between side walls 113a of the channels 113 and the processing target layers 100 and covering the side walls 113a of the channels 113.

A depth CD1 of the channel 113 is, for example, not less than a 32-layer thickness and not more than a 96-layer thickness. The channel 113 has, for example, a circular shape as viewed in a depth direction DD of the channel 113. A width L1 of the channel 113 (a diameter of the channel 113) is, for example, not less than 50 nm and not more than 90 nm.

The semiconductor layer 111 is, for example, made of Si monocrystals. The laminated body 112 includes a plurality of first insulation layers 115 and a plurality of second insulation layers 116. In the laminated body 112, the first insulation layer 115 and the second insulation layer 116 are alternately arranged in the depth direction DD of the channel 113. The first insulation layer 115 is, for example, a silicon oxide layer, and the second layer 116 is, for example, a silicon nitride layer.

A fine uneven pattern is formed on the surface layer portion 110 by the side walls 113a of the channels 113, bottom walls 113b of the channels 113, and a distal end surface 112a of the laminated body 112. The covering layer 114 covers the side walls 113a of the channels 113 and the distal end surface 112a of the laminated body 112. Accordingly, it is possible to prevent the laminated body 112 from being exposed to an etching liquid. As the substrate W having the surface layer portion 110 of such a configuration, a substrate that is used in a manufacturing process of a three-dimensional NAND type flash memory is mentioned.

In a case where the substrate W illustrated in FIG. 7A is applied to the above-mentioned substrate processing, as illustrated in FIG. 7B, a portion of the processing target layer 100 in the channel 113 is etched so that a desired etching depth D1 is achieved. Further, the processing target layer 100 can be etched by wet etching and hence, it is possible to suppress damage to the fine uneven pattern and excessive etching of the processing target layer 100 that become problems in a case where the dry etching such as reactive ion etching is used. The damage to the fine uneven pattern means, for example, a state where a corner portion of the distal end surface 112a of the laminated body 112 is formed into a round shape (a curved shape) by being shaved.

### <Another Example of Change in Surface Layer Portion on Upper Surface of Substrate by Substrate Processing>

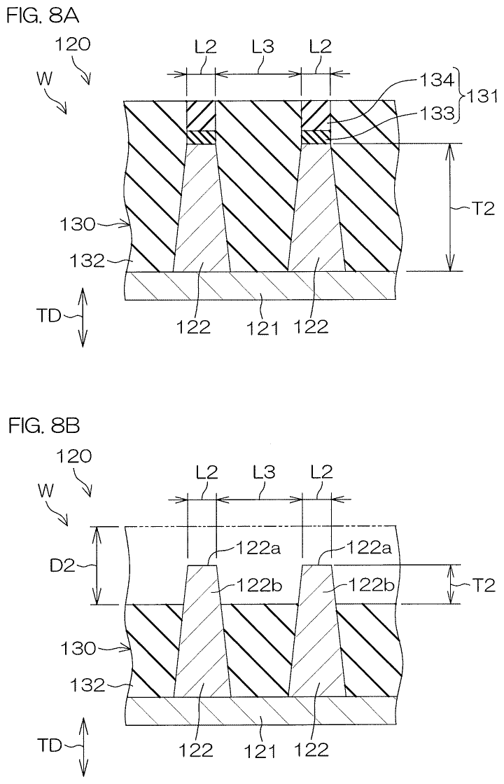

FIG. 8A is a schematic view for describing another example of the structure of a surface layer portion 120 on the upper surface of the substrate W to be processed by the substrate processing apparatus 1. FIG. 8B is a schematic view for describing a change in the structure due to etching of the surface layer portion 120 on the upper surface of the substrate W illustrated in FIG. 8A.

As illustrated in FIG. 8A, the surface layer portion 120 on the upper surface of the substrate W includes a semiconductor layer 121, a plurality of structural bodies 122 formed on the semiconductor layer 121, and a processing target layer 130 that covers the plurality of structural bodies 122. The processing target layer 130 includes: a first processing target layer 131 that is formed on each structural body 122; and a second processing target layer 132 that is positioned between the plurality of structural bodies 122.

The semiconductor layer 121 and the plurality of structural bodies 122 are, for example, made of Si monocrystals. The first processing target layer 131 includes, for example, a first layer 133 formed of a silicon oxide layer, and a second layer 134 formed of a silicon nitride layer formed on the first layer 133. The second processing target layer 132 is, for example, a silicon oxide layer. The second processing target layer 132 is positioned between the structural bodies 122 disposed adjacently to each other, such that the second processing target layer 132 are in contact with the first processing target layer 131 and the structural body 122.

As viewed in a height direction TD of the structural body 122, the structural body 122 is formed in a line shape (a strip shape), and the plurality of structural bodies 122 are arranged at intervals. As viewed in the height direction TD of the structural body 122, a width L2 of the structural body 122 is a width in a short direction of the structural body 122 (an arrangement direction of the structural body 122). For example, the width L2 of the structural body 122 is not less than 5 nm and not more than 22 nm. A width L3 of a gap between the structural bodies 122 is, for example, not less than 24 nm and not more than 60 nm.

A fine uneven pattern is formed on the surface layer portion 120 by the plurality of structural bodies 122. As the substrate W having the surface layer portion 120 of such a configuration, a substrate used in a manufacturing process of a CMOS is mentioned.

In a case where the above-mentioned substrate processing is applied to such a substrate W, as illustrated in FIG. 8B, a portion of the processing target layer 130 is etched so that a desired etching depth D2 is achieved. To be more specific, the entirety of the first processing target layer 131 is removed by etching. Then, a portion of the second processing target layer 132 is removed by etching such that a front surface of the second processing target layer 132 is located at a position closer to the semiconductor layer 121 than distal end portions 122a of the plurality of structural bodies 122. The processing target layer 130 after being etched functions as an interlayer insulation film. The processing target layer 130 can be etched by wet etching and hence, damage to the fine uneven pattern and excessive etching of the processing target layer 130 can be suppressed. In a state where the desired etching depth D2 is achieved, the structural body 122 has a protruding portion 122b that protrudes from the second processing target layer 132. A height T2 of the protruding portion 122b (a distance from the front surface of the second processing target layer 132 after etching to the distal end portion 122a in the height direction TD) is, for example, not less than 34 nm and not more than 60 nm.

### <Modification of Wet Processing Unit>

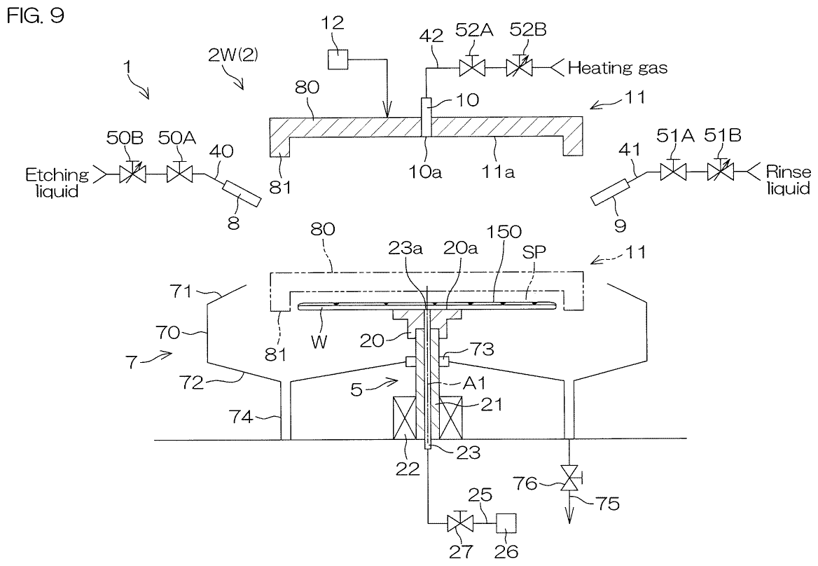

FIG. 9 is a schematic view for describing a modification of the wet processing unit 2W. As illustrated in FIG. 9, the wet processing unit 2W may include, in place of the heating unit 6 (see FIG. 2), a heating gas nozzle 10 that supplies a heating gas that heats the substrate W and the liquid film 150 on the substrate W toward an upper surface of the substrate W. The wet processing unit 2W illustrated in FIG. 9 includes: a facing member 11 that has a facing surface 11a that faces the upper surface of the substrate W; and a facing member elevating/lowering mechanism 12 that elevates/lowers the facing member 11.

The heating gas nozzle 10 includes an ejection opening 10a exposed from the facing surface 11a. A heating gas ejected from the heating gas nozzle 10 is, for example, an inert gas such as a nitrogen gas, air, or a mixed gas of these gases. The inert gas is not limited to a nitrogen gas, and may contain a rare gas such as an argon gas. A temperature of the heating gas is, for example, not less than 50° C. and not more than 200° C.

A heating gas pipe 42 that guides a heating gas to the heating gas nozzle 10 is connected to the heating gas nozzle 10. The heating gas pipe 42 is provided with: a heating gas valve 52A that opens/closes a flow path in the heating gas pipe 42; and a heating gas flow rate adjustment valve 52B that adjusts a flow rate of a heating gas in the heating gas pipe 42. By opening the heating gas valve 52A, a heating gas is ejected from the heating gas nozzle 10 at a flow rate corresponding to the degree of opening of the heating gas flow rate adjustment valve 52B.

The facing member 11 includes: a facing portion 80 having a circular shape that faces the upper surface of the substrate W; and an annular portion 81 that extends downward from a peripheral edge portion of the facing portion 80. The facing surface 11a is, for example, a lower surface of the facing portion 80. The facing member 11 is movable between a close position (a position indicated by an alternate long and two short dashes line in FIG. 9) that is disposed close to the upper surface of the substrate W and a spaced-apart position (a position indicated by a solid liner in FIG. 9) disposed above the close position by the facing member elevating/lowering mechanism 12. When the facing member 11 is located at the close position, the annular portion 81 faces the substrate W from a horizontal direction.

The facing member elevating/lowering mechanism 12 includes, for example, a ball screw mechanism (not illustrated in the drawing) that is joined to the facing member 11, and a motor (not illustrated in the drawing) that imparts a driving force to the ball screw mechanism. The facing member elevating/lowering mechanism 12 is also referred to as a facing member lifter.

When the facing member 11 is located at the close position, a processing space SP is formed by the facing portion 80, the annular portion 81, and the substrate W. By opening the heating gas valve 52A in a state where the processing space SP is formed, a gas in the processing space SP can be speedily replaced with the heating gas. Accordingly, the substrate W and the liquid film 150 can be speedily heated.

### <Configuration of Substrate Processing Apparatus According to Second Embodiment>

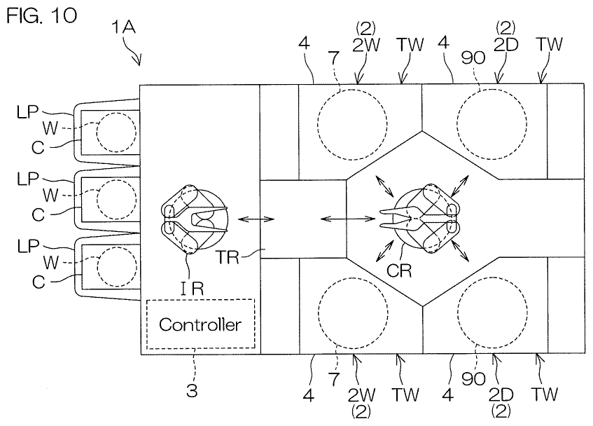

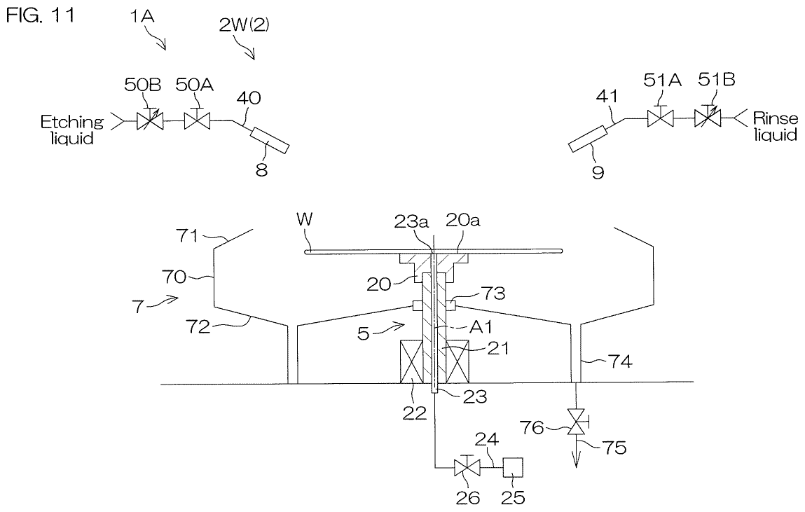

FIG. 10 is an illustrative plan view illustrating a layout of a substrate processing apparatus 1A according to the second embodiment. A plurality of processing units 2 provided in the substrate processing apparatus 1A include a plurality of dry processing units 2D in addition to a plurality of wet processing units 2W.

In the example illustrated in FIG. 10, two processing towers TW disposed on the transfer robot IR side are constituted of a plurality of wet processing units 2W, and two processing towers TW disposed on a side opposite to the transfer robot IR are constituted of a plurality of dry processing units 2D. The dry processing unit 2D includes a heat processing chamber 90 that is disposed in the chamber 4, and heats a substrate W in the dry processing unit 2 in the heat processing chamber 90.

FIG. 11 is a schematic view for describing the configuration of the wet processing unit 2W according to the second embodiment. As illustrated in FIG. 11, the wet processing unit 2W according to the second embodiment is not provided with the configuration that heats the substrate W unlike the first embodiment.

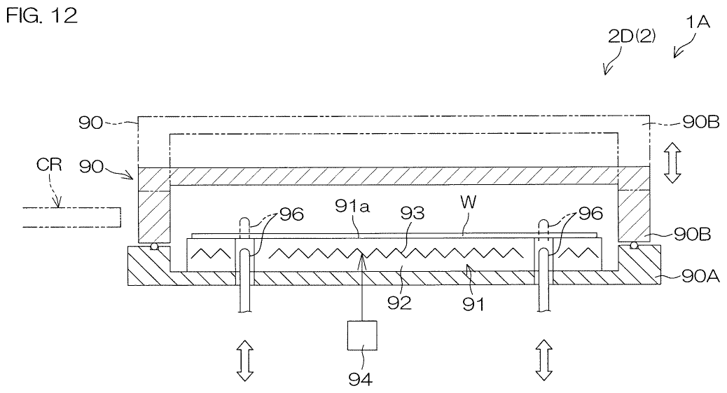

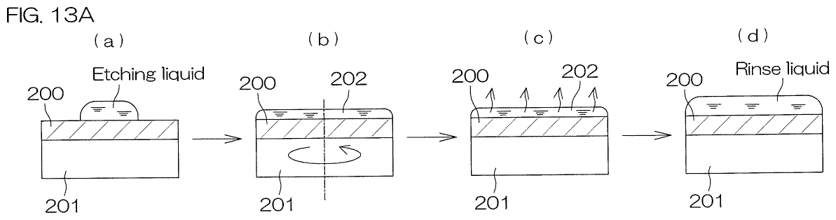

FIG. 12 is a schematic view for describing the configuration of the dry processing unit 2D.

The dry processing unit 2D further includes a heating unit 91 that is housed in the heat processing chamber 90 and has a heating surface 91a on which the substrate W is placed. The heating unit 91 has a form of a hot plate having a disk shape. The heating unit 91 includes a plate body 92 and a heater 93. An upper surface of the plate body 92 forms the heating surface 91a. The heater 93 may be a resistor that is incorporated in the plate body 92. The heater 93 can heat the substrate W to a temperature nearly equal to a temperature of the heater 93. The heater 93 is heated to a setting temperature (for example, not less than 50° C. and not more than 200° C.). To be more specific, an energizing unit 94 such as a power source is connected to the heater 93, and a temperature of the heater 93 changes to a temperature within a predetermined temperature range by adjusting a current supplied from the energizing unit 94.

The heat processing chamber 90 includes: a chamber body 90A that opens upward; and a lid 90B that closes the opening of the chamber body 90A by vertically moving above the chamber body 90A. In a state where the opening of the chamber body 90A is opened (a state illustrated by an alternate long and two short dashes line in FIG. 12), the transfer robot CR can access the inside of the heat processing chamber 90.

The dry processing unit 2D further includes a plurality of lift pins 96 that penetrate the plate body 92 and vertically move. The plurality of lift pins 96 are vertically movable between an upper position (a position indicated by an alternate long and two short dashes line in FIG. 12) at which the lift pins 96 support the substrate W above a heating surface 91a and a lower position (a position indicated by a solid line in FIG. 12) at which distal end portions (an upper end portions) of the lift pins 96 sink below the heating surface 91a.

With the use of the substrate processing apparatus 1A according to the second embodiment, substrate processing the same as the substrate processing according to the first embodiment (see FIG. 4 and FIG. 5) can be performed. However, before and after the heating step (step S4), a transfer of the substrate W is performed between the wet processing unit 2W and the dry processing unit 2D. In the heating step (step S4), a liquid film 150 is heated through the substrate W by the heating unit 91 in a state (a state illustrated by a solid line in FIG. 12) where the plurality of lift pins 96 are disposed at the lower position, and the opening of the chamber body 90A is closed by the lid 90B.

### <Test for Verifying Saturated Atomic Layer Etching>

Next, results of each of the tests performed for verifying saturated atomic layer etching are described.

### [Change-with-Time Test]

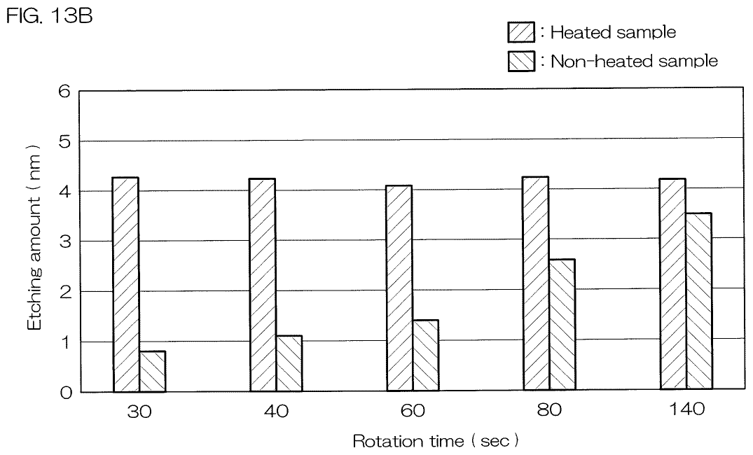

First, description is made with respect to a change-with-time test that is performed for observing time dependency of etching. FIG. 13A is a schematic view for describing steps of the change-with-time test performed for observing time dependency of etching. The change-with-time test was performed in accordance with the following steps (a) to (d).
(a) A substrate having a small-piece shape of 2.5 square cm on which a silicon oxide film having a thickness of 100 nm (hereinafter, referred to as “a small-piece substrate 200”) is formed was placed on a heater 201, and 1 mL of an aqueous ammonium fluoride solution (an etching liquid) was supplied to a major surface of the small-piece substrate 200. A mass percent concentration of the ammonium fluoride (etching agent) in the aqueous ammonium fluoride solution was 2 wt %.
(b) Then, during a predetermined rotation time, the small-piece substrate 200 was rotated by rotating the heater 201. By rotating the small-piece substrate 200, an aqueous ammonium fluoride solution on the small-piece substrate 200 spread over the entirety of the major surface of the small-piece substrate 200 and hence, a thin film 202 of the aqueous ammonium fluoride solution was formed on the major surface of the small-piece substrate 200. At this stage of the processing, the rotation of the small-piece substrate 200 was started at a rotational speed of 500 rpm, and the rotation of the small-piece substrate 200 was accelerated in a stepwise manner such that the rotational speed of the small-piece substrate 200 became 3000 rpm at a point in time of 20 minutes after starting the rotation. Five kinds of small-piece substrates 200 having rotation times of 30 seconds, 40 seconds, 60 seconds, 80 seconds, and 140 seconds respectively were prepared.
(c) Then, heating by the heater 201 was applied to the five kinds of small-piece substrates 200 that were rotated for the respective rotation times. The heating was performed at a temperature of 200° C. for 180 seconds.
(d) Then, the respective small-piece substrates 200 were rinsed by a rinse liquid.

Five kinds of heated small-piece substrates 200 were prepared as “heated samples” in accordance with the above-mentioned steps. On the other hand, small-piece substrates 200 to which the steps (a), (b), and (d) were applied without applying the step (c) were prepared as “non-heated samples.” Then, removal amounts (etching amounts) of silicon oxide films of these samples were measured using a SEM or the like.

FIG. 13B is a graph illustrating results of the change-with-time test that indicates the relationship between the rotation times of the small-piece substrates 200 and the etching amounts. As illustrated in FIG. 13B, in a case where the heated samples were used, the etching amounts were equal in all rotation times, and were approximately 4.0 nm to 4.2 nm. On the other hand, in the case where the non-heated samples were used, a tendency was observed where, with the elapse of time, the etching amounts were increased and gradually approached to 4.0 nm. Accordingly, it is estimated that etching was promoted by heating. In a case where an etching liquid was heated through the small-piece substrate 200, at a point in time that the rotation time elapsed at least 30 seconds, etching was finished. Accordingly, it was indicated that the dependency of etching amount on the rotation time is extremely low.

### [Test on Change in Concentration]

Next, description is made with respect to a test on a change in concentration that was performed for observing concentration dependency of etching. The test on a change in concentration was performed in accordance with the following steps (a) to (d). The steps of the test on a change in concentration are substantially the same as the steps of the change-with-time test described above and hence, the description is made with reference to FIG. 13A.
(a) A small-piece substrate 200 was placed on the heater 201, and 1 m of an aqueous ammonium fluoride solution was supplied to the major surface of the small-piece substrate 200. Five kinds of small-piece substrates 200 where the concentration of ammonium fluoride in the aqueous ammonium fluoride solution supplied to the small-piece substrate 200 were respectively set to 2 wt %, 4 wt %, 6 wt %, and 10 wt % were prepared.
(b) Then, during a predetermined rotation time, the small-piece substrate 200 was rotated by rotating the heater 201. By rotating the small-piece substrate 200, an aqueous ammonium fluoride solution on the small-piece substrate 200 spread over the entirety of the major surface of the small-piece substrate 200 and hence, the thin film 202 of the ammonium fluoride was formed on the major surface of the small-piece substrate 200. At this stage of the processing, the rotation of the small-piece substrate 200 was started at a rotational speed of 500 rpm, and the rotation of the small-piece substrate 200 was accelerated in a stepwise manner such that the rotational speed of the small-piece substrate 200 became 3000 rpm at a point in time of 20 minutes after starting the rotation, and the small-piece substrate 200 was rotated until 80 seconds elapsed since the rotation of the small-piece substrate 200 was started.
(c) Then, heating by the heater 201 was applied to the respective small-piece substrates 200. The heating was performed at a temperature of 200° C. for 180 seconds.
(d) Then, the respective small-piece substrates 200 were rinsed by a rinse liquid.

Five kinds of small-piece substrates 200 were prepared that differ in supply amount of an etching agent in accordance with the above-mentioned steps. Removal amounts (etching amounts) of silicon oxide films of these five kinds of small-piece substrates 200 were measured using a SEM or the like.

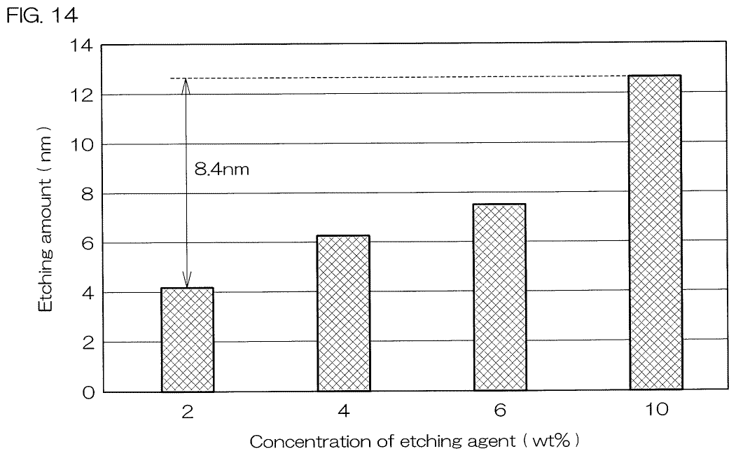

FIG. 14 is a graph illustrating results of the test on a change in concentration. As illustrated in FIG. 14, in a case where the concentration of ammonium fluoride is 2 wt %, an etching amount was approximately 4.1 nm. In a case where the concentration of ammonium fluoride is 4 wt %, an etching amount was approximately 6.1 nm. In a case where the concentration of ammonium fluoride is 6 wt %, an etching amount was approximately 7.5 nm. In a case where the concentration of ammonium fluoride is 10 wt %, an etching amount was approximately 12.5 nm. In this manner, the higher the concentration of ammonium fluoride, the larger the etching amount became. It was indicated that an etching amount changes depending on the concentration of an etching agent. The difference in etching amount within a concentration from 2 wt % to 10 wt % was 8.4 nm.

### [Crystal Observation Test]

Next, description is made with respect to the crystal observation test for observing the generation of crystals in an etching agent liquid. In the crystal observation test, the steps (a) to (d) equal to or below the plurality of concentrations were performed. The steps of the crystal observation test are substantially the same as the steps of the change-with-time test described above and hence, the description is made with reference to FIG. 13A.
(a) A small-piece substrate 200 was placed on the heater 201, and 1 mL of an aqueous ammonium solution was supplied to the major surface of the small-piece substrate 200. Five kinds of small-piece substrates 200 where the concentration of ammonium fluoride in the aqueous ammonium fluoride solution supplied to the small-piece substrate 200 were respectively set to 2 wt %, 4 wt %, 6 wt %, 10 wt %, and 15 wt % were prepared.
(b) Then, during a predetermined rotation time, the small-piece substrate 200 was rotated by rotating the heater 201. At this stage of the processing, the rotation of the small-piece substrate 200 was started at a rotational speed of 500 rpm, and the rotation of the small-piece substrate 200 was accelerated in a stepwise manner such that the rotational speed of the small-piece substrate 200 became 3000 rpm at a point in time of 20 seconds after starting the rotation. With respect to the small-piece substrates 200 to which aqueous ammonium fluoride solutions of the respective concentrations were supplied, five kinds of small-piece substrates 200 having the rotation times of 30 seconds, 40 seconds, 50 seconds, 60 seconds, and 80 seconds respectively were prepared.
(c) Then, heating by the heater 201 was applied to the respective small-piece substrates 200. The heating was performed at a temperature of 200° C. for 180 seconds.
(d) Then, the respective small-piece substrates 200 were rinsed by a rinse liquid.

In accordance with such steps, plural kinds (25 kinds in total) of small-piece substrates 200 that differ in rotation time and supply amount of an etching agent were prepared. States of major surfaces of these plural kinds of small-piece substrates 200 were measured using a SEM or the like.

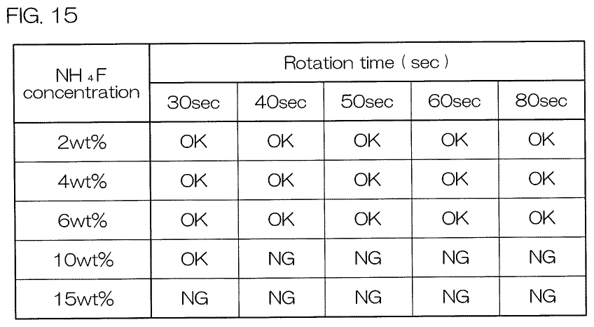

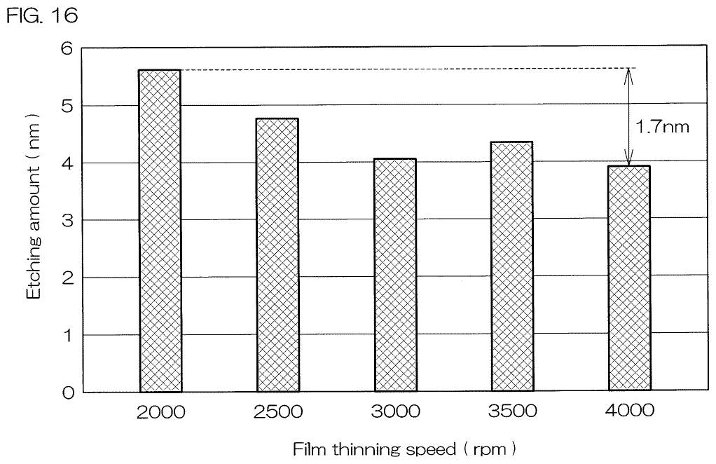

FIG. 15 is a table illustrating results of a crystal observation test. As illustrated in FIG. 15, in a case where the mass percent concentrations of ammonium fluoride in an aqueous ammonium fluoride solution are 2 wt %, 4 wt %, and 6 wt %, regardless of a rotation time of the small-piece substrates 200, the generation of crystals was not observed. On the other hand, in the case where the mass percent concentration of ammonium fluoride in the aqueous ammonium fluoride solution is 10 wt %, the generation of crystals was observed when the rotation time is longer than 30 seconds. Further, in the case where the mass percent concentration of ammonium fluoride in the aqueous ammonium fluoride solution is 15 wt %, regardless of the rotation time, the generation of crystals was observed. Due to the generation of crystals, there is a concern that the uniformity of etching on the major surface of the small-piece substrates 200 is lowered.

The followings are estimated based on the results of the test on a change of concentration indicated in FIG. 14 and the crystal observation test in FIG. 15. In the case where the mass percent concentration of ammonium fluoride in the etching liquid is less than 10 wt %, a silicon oxide film can be sufficiently etched while maintaining in-plane uniformity of etching. Particularly, in the case where the mass percent concentration of ammonium fluoride in the etching liquid is not less than 2 wt % and less than 10 wt %, such an effect can be easily provided. In the case where the mass percent concentration of the ammonium fluoride in the etching liquid is not less than 2 wt % and not more than 6 wt %, such an effect can be more easily provided.

### [Test on Change in Rotational Speed]

Next, description is made with respect to a test on a change in rotational speed for observing rotational speed dependency of etching. The test on a change in rotational speed was performed in accordance with the following steps (a) to (d). The steps of the test on a change in the rotational speed are substantially the same as the steps of the change-with-time test described above and hence, the description is made with reference to FIG. 13A.
(a) A small-piece substrate 200 was placed on the heater 201, and 1 mL of an aqueous ammonium fluoride solution where the mass percent concentration of ammonium fluoride was 2 wt % was supplied to the major surface of the small-piece substrate 200.
(b) Then, during a predetermined rotation time, the small-piece substrate 200 was rotated by rotating the heater 201. By rotating the small-piece substrate 200, an aqueous ammonium fluoride solution on the small-piece substrate 200 spread over the entirety of the major surface of the small-piece substrate 200 and hence, the thin film 202 of the ammonium fluoride was formed on the major surface of the small-piece substrate 200. At this stage of the processing, the rotation of the small-piece substrate 200 was started at a rotational speed of 500 rpm, and the rotation of the small-piece substrate 200 was accelerated such that the rotational speed of the small-piece substrate 200 became a predetermined film thinning speed at a point in time of 5 seconds after starting the rotation. Until a point in time that approximately 80 seconds elapsed after starting the rotation, the rotation of the small-piece substrate 200 at the film thinning speed was continued. Five kinds of small-piece substrates 200 where the film thinning speed was set to 2000 rpm, 2500 rpm, 3000 rpm, 3500 rpm, and 4000 rpm respectively were prepared.
(c) Then, heating by the heater 201 was applied to the five kinds of small-piece substrates 200 rotated for the respective rotation times. The heating was performed at a temperature of 180° C. for 180 seconds.
(d) Then, the respective small-piece substrates 200 were rinsed by a rinse liquid.

In accordance with such steps, five kinds of small-piece substrates that differ in film thinning speed were prepared. Removal amounts (etching amounts) of silicon oxide films of these five kinds of small-piece substrates 200 were measured using a SEM or the like.

FIG. 16 is a graph illustrating results of the test on a change in rotational speed. As indicated in FIG. 16, in the case where the film thinning speed falls within a range of not less than 2000 rpm and not more than 3000 rpm, a tendency that the etching amount is reduced with an increase in film thinning speed was observed. To be more specific, when the film thinning speed was 2000 rpm, the etching amount was approximately 5.6 nm, when the film thinning speed was 2500 rpm, the etching amount was approximately 4.8 nm, and when the film thinning speed was 3000 rpm, the etching amount was approximately 4.1 nm. In this manner, it was indicated that the etching amount changes depending on the film thinning speed.

In the case where the film thinning speed falls within a range of not less than 3000 rpm and not more than 4000 rpm, the etching amount was approximately constant regardless of the film thinning speed. The reason is considered as follows. At a point of time that the film thinning speed reaches 3000 rpm, an aqueous ammonium fluoride solution on the small-piece substrate 200 was formed into a thin film having a limit thickness and hence, even when the rotational speed was increased, a change did not occur with respect to an amount of the aqueous ammonium fluoride solution on the small-piece substrate 200 and hence, a change did not occur in the etching amount within the above-mentioned range of the rotational speed.

While a change amount of an etching amount due to a change in film thinning speed was approximately 1.7 nm, in the test on a change in concentration (see FIG. 14), a change amount of an etching amount due to a change in concentration of ammonium fluoride was approximately 8.4 nm at maximum. Accordingly, it is estimated that an etching amount can be finely controlled in the adjustment of a film thinning speed, that is a control of a rotational speed of the substrate.

### [Test on Change in Temperature]

Next, description is made with respect to a test on a change in temperature for observing heating temperature dependency of etching. The test on a change in temperature was performed in accordance with the following steps (a) to (d). The steps of the test on a change in temperature are substantially the same as the steps of the change-with-time described above and hence, the description is made with reference to FIG. 13A.
(a) A small-piece substrate 200 was placed on the heater 201, and 1 mL of an aqueous ammonium fluoride solution where the mass percent concentration of ammonium fluoride was 2 wt % was supplied to the major surface of the small-piece substrate 200.
(b) Then, during a predetermined rotation time, the small-piece substrate 200 was rotated by rotating the heater 201. By rotating the small-piece substrate 200, an aqueous ammonium fluoride solution on the small-piece substrate 200 spread over the entirety of the major surface of the small-piece substrate 200 and hence, a thin film of the ammonium fluoride was formed on the major surface of the small-piece substrate 200. At this stage of the processing, the rotation of the small-piece substrate 200 was started at a rotational speed of 500 rpm, and the rotation of the small-piece substrate 200 was accelerated in a stepwise manner such that the rotational speed of the small-piece substrate 200 became 3000 rpm at a point in time of 20 seconds after starting the rotation, and the small-piece substrate 200 was rotated until 80 seconds elapsed since the rotation of the small-piece substrate 200 was started.
(c) Then, heating by the heater 201 was applied to the small-piece substrates 200. Four kinds of small-piece substrates 200 having heating temperatures of 50° C., 80° C., 150° C., and 180° C. were prepared.
(d) Then, the respective small-piece substrates 200 were rinsed by a rinse liquid.

In accordance with such steps, four kinds of small-piece substrates 200 that differ in heating temperature were prepared. Removal amounts (etching amounts) of silicon oxide films on these four kinds of small-piece substrates 200 were measured using a SEM or the like.

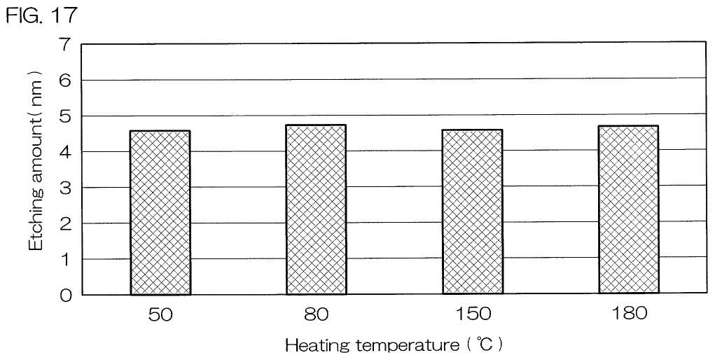

FIG. 17 is a graph illustrating results of the test on a change in temperature. As indicated in FIG. 17, at all heating temperatures, the etching amounts were approximately 4.5 nm. Accordingly, it was indicated that, provided that the heating temperature falls at least within a range of not less than 50° C. and not more than 180° C., the etching can be performed sufficiently regardless of the heating temperature.

### Other Embodiments

The present invention is not limited to the embodiments described above, and the present invention can be carried out in yet other embodiments.
(1) For example, in the above-mentioned respective embodiments, the substrate processing is performed with respect to the upper surface of the substrate W. However, the substrate processing may be performed with respect to the lower surface of the substrate W.
(2) In the above-mentioned respective embodiments, the spin chuck 5 is a vacuum-suction type spin chuck that suctions the substrate W to the spin base 20. However, the spin chuck 5 may be a grip-type spin chuck that grips a peripheral edge of the substrate W by a plurality of chuck pins.
(3) It is not always necessary that the spin chuck 5 holds the substrate W horizontally. That is, unlike the case illustrated in FIG. 3, the spin chuck 5 may hold the substrate W vertically, or may hold the substrate W such that the upper surface of the substrate W is inclined with respect to a horizontal surface.
(4) In the above-mentioned respective embodiments, a description has been made that a solid formed by a reaction between an etching agent in the etching liquid and the processing target layer is decomposed by heating and hence, the reaction between the etching agent and the processing target layer is promoted. However, the reaction between the etching agent and the processing target layer may be promoted due to a phenomenon that a material that is formed by the reaction between the etching agent and the processing target layer is not decomposed, and becomes a gas (mainly sublimation) due to a change of state.
(5) Unlike the above-mentioned embodiments, the rotation of the substrate W in the etching liquid supply step may be stopped.
(6) In the above-mentioned respective embodiments, there is an arrangement such that a plurality of fluids are respectively ejected from a plurality of nozzles. However, modes of ejection of the respective fluids are not limited to the above-mentioned respective embodiments.

For example, the respective processing liquid nozzles may be movable nozzles that are movable in the horizontal direction. Further, all processing liquid nozzles may be arranged to be moved integrally by a single nozzle moving mechanism. Further, the arrangement may be adopted such that the entire fluids are ejected toward the upper surface of the substrate W from a single nozzle.
(7) In the above-mentioned respective embodiments, the illustration of pipes, pumps, valves, actuators and the like is partially omitted. However, such omission of the members is not intended to mean that these members do not exist, and these members are disposed at appropriate positions in actual configurations. For example, a flow rate adjustment valve (not illustrated in the drawing) that adjusts a flow rate of a processing liquid ejected from a corresponding processing liquid nozzle may be provided in each pipe.
(8) In the above-mentioned respective embodiments, the controller 3 controls the entirety of the substrate processing apparatus 1. However, the controller that controls the respective members of the substrate processing apparatus 1 may be distributed in multiple places. Further, it is not always necessary that the controller 3 directly controls the respective members. That is, signals output from the controller 3 may be received by slave controllers that control the respective members of the substrate processing apparatus 1.
(9) Further, in the above-mentioned embodiments, the substrate processing apparatus 1 includes the transfer robots IR, CR, the plurality of processing units 2, and the controller 3. However, the substrate processing apparatus 1 may be constituted of the single processing unit 2 and the controller 3, and may not include the transfer robots. Alternatively, the substrate processing apparatus 1 may be constituted of only the single processing unit 2. In other words, the processing unit 2 may be one example of the substrate processing apparatus.

The embodiments of the present invention are described in detail above, however, these are just detailed examples used for clarifying the technical contents of the present invention, and the present invention should not be limitedly interpreted to these detailed examples, and the scope of the present invention should be limited only by the claims appended hereto.

### REFERENCE SIGNS LIST

100: Processing target layer
112: Laminated body (insulation layer)
113: Channel
114: Covering layer
121: Semiconductor layer
122: Structural body
130: Processing target layer
151: Solid layer
A1: Rotational axis (center axis)
D: Etching depth (etching amount)
D1: Etching depth (etching amount)
D2: Etching depth (etching amount)
W: Substrate

1. A substrate processing method to process a substrate having a major surface in which at least one of a silicon oxide layer and a silicon nitride layer is exposed as a processing target layer, the substrate processing method comprising:
an etching liquid supply step of supplying the major surface of the substrate with an etching liquid containing an ammonium fluoride as an etching agent to etch the processing target layer;
a heating step of heating the etching liquid on the major surface of the substrate after the etching liquid supply step; and
a rinse liquid supply step of supplying the major surface of the substrate with a rinse liquid after the heating step.

2. The substrate processing method according to claim 1, further comprising a rotating step of rotating the substrate about a center axis that passes a center portion of the major surface of the substrate after stopping the supply of the etching liquid to the major surface of the substrate in the etching liquid supply step and before the heating step.

3. The substrate processing method according to claim 2, wherein the rotating step includes a step of rotating the substrate at a rotational speed of not less than 2000 rpm and not more than 4000 rpm.

4. The substrate processing method according to claim 1, wherein a mass percent concentration of the etching agent in the etching liquid to be supplied to the major surface of the substrate is not less than 0.2 wt % and less than 10 wt %.

5. The substrate processing method according to claim 1, wherein, in the heating step, the substrate is heated to a temperature of not less than 50° C. and not more than 200° C.

6. The substrate processing method according to claim 1, wherein an etching depth of the processing target layer is proportional to a total amount of the etching agent in the etching liquid existing on the major surface of the substrate at the time of starting the heating step.

7. The substrate processing method according to claim 1, wherein the heating step includes a reaction promoting step of promoting a reaction between the etching agent and the processing target layer by removing by heating a solid layer formed on the processing target layer by a reaction between the etching agent in the etching liquid on the major surface of the substrate and the processing target layer.

8. The substrate processing method according to claim 1, wherein the substrate further includes an insulation layer, a channel that is formed by digging a front surface of the insulation layer and in that the processing target layer is embedded, and a covering layer interposed between the processing target layer and a side wall of the channel and covering the side wall of the channel.

9. The substrate processing method according to claim 1, wherein the substrate further includes a semiconductor layer, and a plurality of structural bodies formed on the semiconductor layer, the plurality of structural bodies being covered by the processing target layer.
